(19) United States
(12) Patent Application Publication
(10) Pub. No.: US 2024/0012405 A1
(43) Pub. Date: Jan. 11, 2024

(54) Method and Device for Determining a Remaining Service Life of a Technical System

(71) Applicant: Robert Bosch GmbH, Stuttgart (DE)

(72) Inventor: Achim Romer, Weinsberg (DE)

(21) Appl. No.: 18/255,859

(22) PCT Filed: Dec. 1, 2021
(86) PCT No.: PCT/EP2021/083718

§ 371 Date: Jun. 2, 2023

(30) Foreign Application Priority Data
Dec. 4, 2020 (DE) 10 2020 215 378.7

(51) Int. Cl. G05B 23/02

(52) U.S. Cl. CPC G05B 23/0229

(57) ABSTRACT

A computer-implemented method for determining a remaining service life of at least one component of a technical system is disclosed. The method includes (i) determining a first input signal by way of at least one sensor, wherein the first input signal characterizes an operating state of at least the component of the technical system, (ii) determining a first representation of the first input signal by way of an encoder of a first machine learning system, and (iii) determining the remaining service life on the basis of the first representation and on the basis of a provided plurality of second representations, wherein the plurality of second representations is determined on the basis of a plurality of second input signals by way of the encoder and a corresponding remaining service life is assigned to each second representation.

### TECHNICAL FIELD

The invention relates to a method for determining a remaining service life of a technical system, a device for carrying out the method, a method for training a machine learning system, a device for training the machine learning system, a computer program, and a machine-readable storage medium.

### PRIOR ART

A method for determining a representation by means of an auto encoder is known from Hinton and Salakhutdinov, “Reducing the Dimensionality of Data with Neural Networks”, Jul. 28, 2006, https://www.cs.toronto.edu/˜hinton/science.pdf.

### Advantages of the Invention

Technical systems, or at least components of technical systems, are generally subject to wear processes. These wear processes can cause a technical system to no longer function efficiently or even correctly. This can lead, among other things, to a failure of the technical system.

It is therefore desirable to determine a remaining useful life (also rest of useful life (RUL) or remaining service life) of a technical system or at least one component of a technical system. Based on the determined remaining useful life, it is possible to decide whether and/or when to replace the technical system or the component, for example.

The method with features of independent claim 1 enables the determination of a remaining useful life of a technical system or at least one component of the technical system. This is advantageous because it allows a failure of the technical system or the technical component to be avoided. It is also possible for maintenance of the technical system or at least the component of the technical system to be carried out based on the determined remaining useful life. The advantage of the method is that the remaining service life can be determined with a greater accuracy.

### DISCLOSURE OF THE INVENTION

In a first aspect, the invention relates to a computer-implemented method for determining a remaining service life of at least one component of a technical system, wherein the method comprises the following steps:
determining a first input signal by means of at least one sensor, wherein the first input signal characterizes an operating state of at least the component of the technical system;
determining a first representation of the first input signal by means of an encoder of a first machine learning system;
determining the remaining service life on the basis of the first representation and on the basis of a provided plurality of second representations, wherein the plurality of second representations is determined on the basis of a plurality of second input signals by means of the encoder and a corresponding remaining service life is assigned to each second representation.

In the described method, a remaining service life can be understood to be a period of time from a current point in time to a second point in time, within which the component and/or the technical system itself carries out or can carry out an intended function correctly or with sufficient accuracy or with sufficient efficiency, whereas, after the second point in time, a malfunction of the component and/or the technical system occurs or the component and/or the technical system does not or cannot carry out the intended function with sufficient accuracy or sufficient efficiency or further operation of the component and/or the technical system can lead to a safety risk.

It is conceivable that the technical system is a brake and the component is a brake disc, for example. In this example, it is conceivable that the brake no longer functions correctly after the second point in time due to wear of the brake disc, or that further operation leads to too high a risk, e.g., because the brake can no longer develop sufficient braking force.

The method can therefore be understood as determining a remaining service life of the component and/or the technical system by means of the first machine learning system.

For this purpose, the first input signal, which characterizes an operating state of the component or the technical system, is first determined in the method by means of the at least one sensor. The used sensor can, for example, be a sensor that is configured to determine a temperature, a pressure, a speed of rotation, a flow, or an acceleration. It is advantageously also possible to use multiple potentially different sensors. The input signal can then preferably be presented in the form of a vector. It is also possible to use an optical sensor as the sensor, however, and for the input signal to include an image.

The input signal is then received by the first machine learning system, which uses the encoder to determine the first representation that can be understood as a latent representation of the input signal. The encoder can be understood here as a device that can extract information relevant for determining the remaining service life from the input signal.

The first machine learning system can in particular include an auto encoder, wherein the encoder of the auto encoder can be understood as the encoder of the first machine learning system. In this case, the encoder of the auto encoder can receive the input signal and determine an output, wherein the output can be used as the first representation. It is also possible that the output determined by the encoder undergoes at least one post-processing step and the post-processed output is used as the first representation.

It is also possible for the first machine learning system to include a variational auto encoder, wherein the encoder of the variational auto encoder can be understood as the encoder of the first machine learning system. In this case, the encoder of the auto encoder can receive the input signal and determine an output comprising at least one first value which characterizes an expected value and comprising at least one second value which characterizes a variance. The first and second value or the first and the second values can preferably be concatenated into a vector, wherein the vector can be provided as the first representation. It is also possible that the vector undergoes at least one post-processing step and the post-processed vector is used as the first representation.

However, it is also possible for the first machine learning system to comprise a normalizing flow, wherein the forward direction of the normalizing flow can be understood as the encoder. In this case, the normalizing flow can receive the input signal and determine an output by means of a forward pass, wherein the output can be used as the first representation. It is also possible that the output determined by the normalizing flow undergoes at least one post-processing step and the post-processed output is used as the first representation.

Irrespective of the choice of encoder, the post-processing can include at least one shift in accordance with an average value of the second representations.

The first representation and the second representations can be understood as points or vectors of a latent subspace of the space of the input signals, wherein the latent subspace respectively characterizes relevant information present in the first input signal and the second input signals.

The determined first representation can then be compared to the plurality of second representations in order to determine the remaining service life. The second representations can in particular be determined during a development time of the component and/or the technical system. Second input signals of a structurally identical or structurally similar component or a structurally identical or structurally similar technical system can be recorded and determined during the development time, for example, and the component reaching a second point in time can be awaited. The respective time interval from the time at which the second input signal was received to the second time can then be assigned to a second input signal as the remaining service life.

The first machine learning system can then be trained with the second input signals and the respective corresponding, i.e., assigned, remaining service lives. After training, the second input signals can be processed by the encoder of the first machine learning system and the output of the encoder can be provided as second representations. The remaining service life determined for a second input signal can then be assigned to a second representation determined for the second input signal.

In a preferred form of the method, it is also possible that, in the step of determining the remaining service life, the remaining service life is determined depending on at least one similarity of one of the second representations to the first representation.

The advantage of this approach is that the method can predict the remaining service life very accurately, because the encoder compresses the information of the first input signal to a subset of information that substantially characterizes the first input signal. A comparison of the first representation with the second representations using the similarity can thus be viewed as a comparison of the semantic contents of the respective input signals, wherein unwanted content of the input signals, such as noise, has been removed from the input signals by the encoder. This can improve the accuracy of the prediction of the remaining service life.

The similarity can in particular be determined on the basis of a standard or a distance. A numerically large standard or a numerically large distance can be understood here as a small degree of similarity and a numerically small standard or a numerically small distance can be understood as a high degree of similarity. Similarity can also be determined using approximative methods, in particular a locality-sensitive hashing method.

It is in particular possible that the remaining service life assigned to a second representation is provided as the determined remaining service life, wherein the second representation is the one of the plurality of second representations that is most similar to the first representation.

This format can be understood such that a nearest neighbor is determined for the first representation within the second representations and its remaining service life is provided as the remaining service life. The advantage of this format is that a remaining service life can be determined very quickly by using the nearest neighbor. Another advantage is that it can also be determined whether the similarity to the nearest neighbor is within a typical similarity interval or whether the similarity to the nearest neighbor is much smaller than a typical similarity. A typical similarity of a second representation to its respective nearest neighbor can be used as a typical similarity, for example. If the similarity to the nearest neighbor is atypical, this can indicate an anomaly in the input signal and/or in the component and/or in the technical system.

In a preferred embodiment of the method, it is also possible that an average or a median or a minimum or a maximum of remaining service lives corresponding to a subset of the plurality of second representations is provided as the determined remaining service life, wherein the subset includes a predefined number of second representations most similar to the first representation.

This format can be understood as first determining a predefined number of nearest neighbors within the second representations for the first representation and then providing an average or a median or a minimum or a maximum of the remaining service lives corresponding to the determined nearest neighbors as the remaining service life. The advantage of this approach is that the information from a plurality of nearest neighbors enables a more differentiated determination of the remaining service life. A remaining service life determined by means of the median or the average can, for example, be understood as an expected remaining service life. A remaining service life determined by means of the minimum can be understood as a worst expected remaining service life, whereas a remaining service life determined by means of the maximum can be understood as a best expected remaining service life. This is advantageous because an operator and/or user of the technical system can thus be given direct insight into the life cycle of the component and/or the technical system. For example, it is possible for the operator and/or user of the technical system to be shown an expected remaining service life as well as a minimum expected remaining service life and a maximum expected remaining service life. This information makes it possible for the operator and/or user of the technical system to decide how long the technical system can or should still be operated.

In a further form of the method, it is possible that the remaining service life is determined by means of a second machine learning system, wherein the second machine learning system is initially trained by means of the plurality of second representations and the remaining service lives respectively assigned to the second representations such that it can determine a remaining service life for the first representations.

It is in particular possible that the remaining service life assigned to a second representation is shown as a real number, e.g., in seconds. In this case, the second machine learning system can in particular be trained as a regressor, i.e., the second machine learning system is trained such that it receives a second representation and then predicts the assigned remaining service life. A supervised learning method can then preferably be used for training in order to train the second machine learning system. After training, the second machine learning system can then predict the remaining service life on the basis of the first representation. The advantage of this form is that the second machine learning system also makes it possible to learn highly non-linear relationships between the second representations and the assigned remaining service lives, in particular if a neural network is used for the regression. This further improves the accuracy of the prediction of the remaining service life.

In a further form of the method, it is conceivable that the first representation is transmitted to a second device by means of a network connection of the technical system and the step of determining the remaining service life is carried out by the second device.

This form can be understood such that the determination of the first representation is carried out by the technical system itself, while the determination of the remaining service life is carried out by the second device. This makes it possible for the technical system itself to not have to hold the second representations available, but rather that these can preferably be held available decentrally by the second device. This reduces the need for memory space and the need for computing capacity of the technical system, because the search for the nearest neighbor or the evaluation by the second machine learning system is carried out by the second device.

In a further preferred form of the method, it is possible that the first representation is held available by the technical system and/or the second device together with a measurement time for the input signal and, at an end of a life of at least the component of the technical system, the first representation is included as a second representation in the plurality of the second representations, wherein the remaining service life corresponding to the first representation is determined by a difference of a time of the end of life and the measurement time.

If the second machine learning system is used to determine the remaining service life, the second machine learning system can be retrained or trained again with the expanded plurality of second representations after representations are added to the plurality of second representations.

This form can be understood such that further input signals are collected during the operating time of the technical system, which can then be included in the plurality of the second input signals as soon as the end of life of the component and/or the technical system is reached. A second point in time can be understood as the end of life. The advantage of this form is that the plurality of second input signals can be further increased during the operation of the technical system. As a result, the accuracy of determining the remaining service life can be further improved.

In a further form of the method, it is possible that the determined remaining service life is communicated to an operator and/or a user of the technical system by means of a display device.

This is advantageous, because the operator and/or user of the technical system can thus be informed about the internal state of the technical system and enabled, for example, to decide whether the component and/or the technical system should be replaced or taken out of service.

It is also possible for at least the component of the technical system to be replaced if the determined remaining service life reaches or falls below a predefined minimum remaining service life.

The replacement can preferably take place automatically, for example by means of a robot configured for this purpose. This has the advantage that downtimes of the technical system can be greatly reduced by preventing wear-related failures of the component and/or the technical system.

It is also possible for the range of functions of the technical system to be restricted as soon as the remaining service life falls below a predefined minimum remaining service life.

For example, it is conceivable that the use of the component and/or the technical system poses a greatly increased safety risk once the determined remaining service life reaches or falls below the predefined remaining service life. An example of this is the example of the brake from above. It is possible that the brake is configured to slow a motor vehicle, in particular to slow an at least partially automated motor vehicle. In this case, it is further possible that the range of functions of the motor vehicle is restricted as soon as the determined remaining service life reaches or falls below the predefined remaining service life. For example, it is conceivable that the maximum speed of the motor vehicle is restricted when the predefined remaining service life is reached or undershot to reduce the probability of an accident as a result of the decreased braking force of the brake. This advantageously increases the safety of the technical system.

In a preferred form of the method, it is possible for the technical system to be an at least partially automated motor vehicle or a manufacturing system or a household appliance.

Embodiments of the invention are explained in more detail in the following with reference to the accompanying drawings. The drawings show:

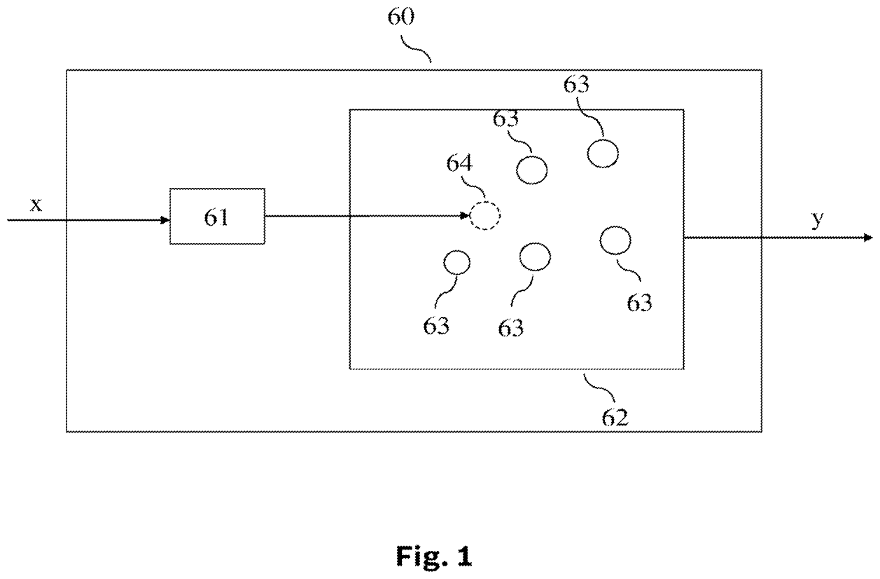

FIG. 1 schematically a structure of a control system for controlling an actuator;

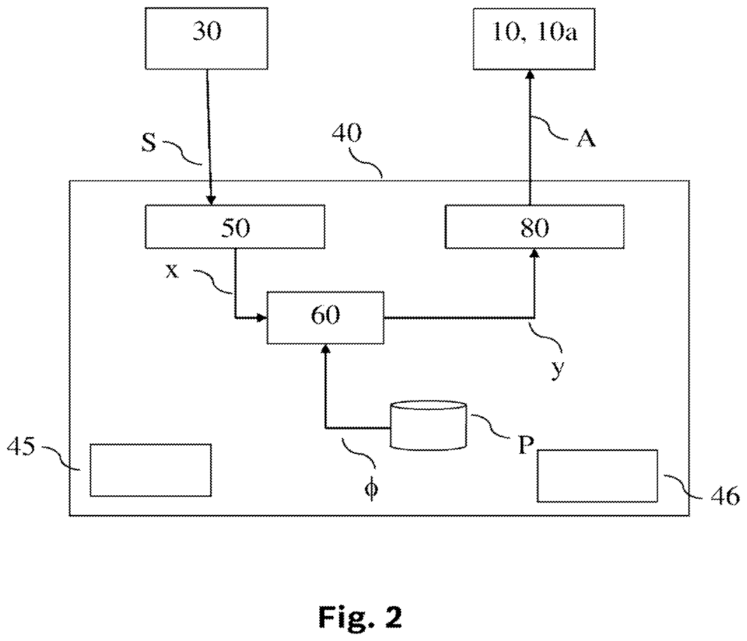

FIG. 2 schematically an embodiment example for controlling an at least partially autonomous robot;

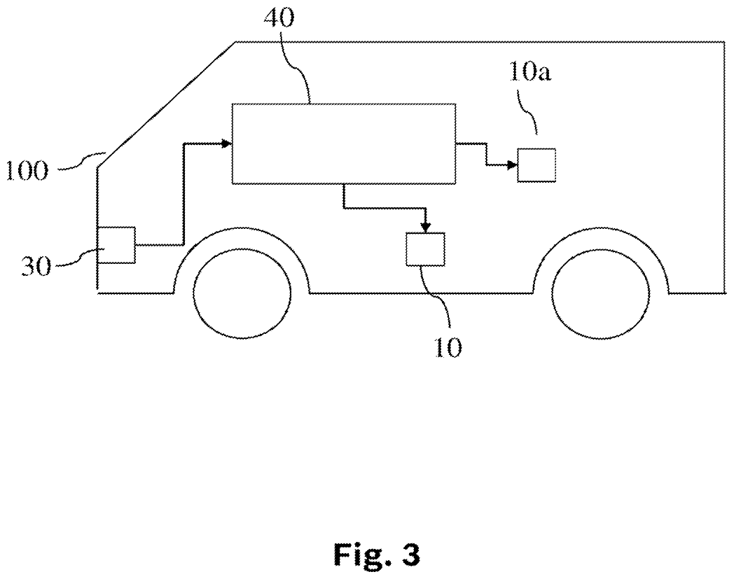

FIG. 3 schematically an embodiment example for controlling a manufacturing system;

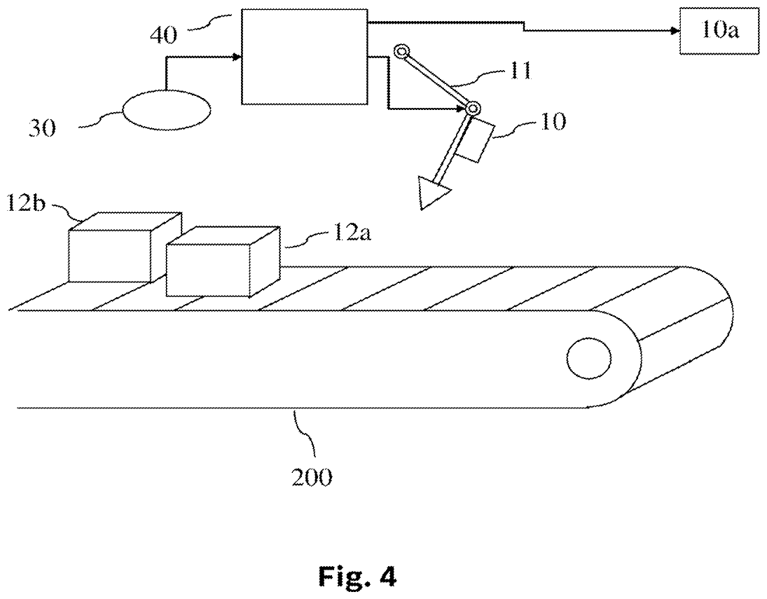

FIG. 4 schematically an embodiment example for controlling an access system;

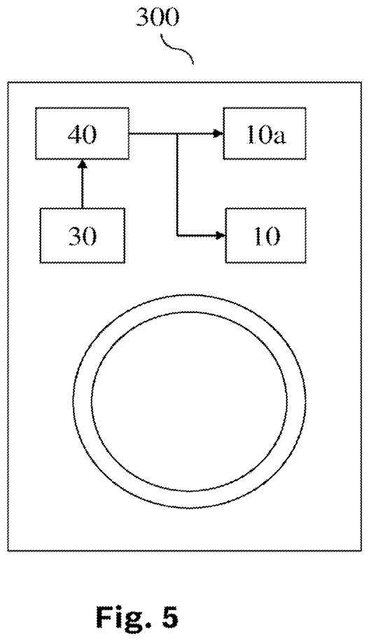

FIG. 5 schematically an embodiment example for controlling a monitoring system;

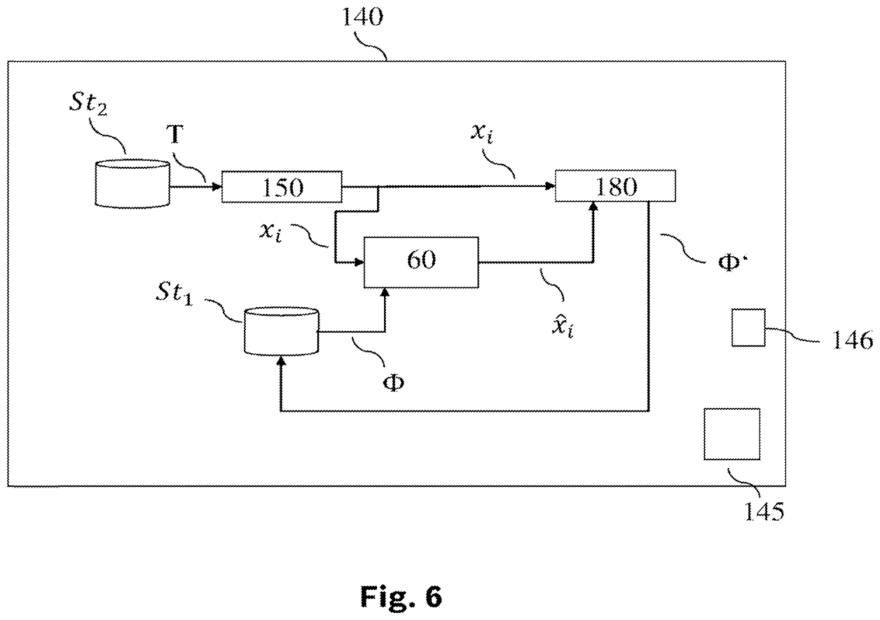

FIG. 6 schematically an embodiment example for controlling a personal assistant.

### DESCRIPTION OF THE EMBODIMENT EXAMPLES

FIG. 1 shows a first machine learning system (60), which is configured to receive an input signal (x) and determine an output signal (y) on the basis of the input signal (x), wherein the input signal (x) characterizes an operating state of at least one component of a technical system and the output signal (y) characterizes a remaining service life of at least the component of the technical system.

The input signal can preferably characterize a temperature and/or a pressure and/or a current and/or a voltage and/or a rotation rate and/or an acceleration of at least the component of the technical system and can be recorded with one or more suitable sensors.

The input signal (x) is fed to an encoder (61) of the first machine learning system, wherein the encoder (61) is configured to determine a first representation (64) from the input signal (x). The encoder (61) outputs the first representation (64), preferably in the form of a vector, a matrix or a tensor.

The first representation is fed to a comparison unit (62). The comparison unit (62) can comprise a plurality of second representations (63) which can be compared to the first representation (64), i.e., the form of the second representations is the same as the form of the first representations. The second representations (63) have preferably been determined with encoders (61) from second input signals. The second input signals are each assigned remaining useful lives, which can be applied to the correspondingly determined second representations. Each second representation therefore has a corresponding remaining service life. The remaining service lives can preferably be characterized by a real value which indicates the remaining service life in seconds.

The comparison unit (62) can then determine at least one, preferably a plurality of, nearest neighbors of the first representation (64) within the plurality of second representations (63). To determine the nearest neighbor or neighbors, a similarity of the first representation (64) to the respective second representations (63) can be determined. A suitable standard can in particular be used to determine the similarity, e.g., the Euclidean distance or a cosine similarity.

The remaining service life of the second representation most similar to the first representation (64), i.e., the remaining service life of the nearest neighbor, can then be determined by the comparison unit (62) as the remaining service life corresponding to the first input signal (x) and output as at least part of the output signal (y). Alternatively, it is also possible that an average and/or a median and/or a minimum and/or a maximum of the remaining service lives of the plurality of nearest neighbors is determined as the remaining service life corresponding to the first input signal (x) and output as at least part of the output signal (y).

Alternatively, it is also possible that the comparison unit (62) comprises a second machine learning system (not shown) which receives the first representation (64) as an input. The second machine learning system has preferably been trained with the second representations (63) and the corresponding remaining service lives such that the second machine learning system can determine a remaining service life for the first representation. The second machine learning system can therefore be understood to carry out a regression method. For this purpose, the second machine learning system can in particular comprise a neural network which is configured to receive a representation and to predict a remaining service life. The remaining service life determined by the second machine learning system can then be output as at least part of the output signal (y).

FIG. 2 shows a control system (40) for controlling a technical system. The control system (40) receives sensor signals (S) of at least one sensor (30) in an optional receiving unit (50) which converts the sensor signals (S) to first input signals (x) (one respective sensor signal (S) can alternatively also be accepted directly as an input signal (x)). The at least one sensor (30) is configured to determine an operating state of at least one component of the technical system. The input signal (x) can be a section or a further processing of the sensor signal (S), for example. In other words, the input signal (x) is determined depending on the sensor signal (S). The sequence of input signals (x) is fed to the first machine learning system (60).

The first machine learning system (60) is preferably parameterized by parameters (ϕ), which are stored in and provided by a parameter memory (P).

The first machine learning system (60) determines an output signal (y) from an input signal (x). The output signal (y) is fed to an optional conversion unit (80), which uses it to determine control signals (A) that are fed to an actuator (10) in order to accordingly control the actuator (10).

The actuator (10) receives the control signals (A), is accordingly controlled and carries out a corresponding action. The actuator (10) can comprise a (not necessarily structurally integrated) control logic which, from the control signal (A), determines a second control signal which is then used to control the actuator (10).

In further embodiments, the control system (40) includes the sensor (30). In still further embodiments, the control system (40) alternatively or additionally also includes the actuator (10).

In further preferred embodiments, the control system (40) comprises at least one processor (45) and at least one machine-readable storage medium (46) on which instructions are stored that, when executed on the at least one processor (45), prompt the control system (40) to carry out the method according to the invention.

In alternative embodiments, a display unit (10a) is provided alternatively or additionally to the actuator (10).

FIG. 3 shows how the control system (40) can be used to control an at least partially autonomous robot, here an at least partially autonomous motor vehicle (100). For example, it is possible for the control system (40) to receive sensor data (S) from a brake of the motor vehicle (100), wherein a remaining service life of the brake of the motor vehicle is determined on the basis of said sensor data (S). In particular sensors (30) that can determine a temperature of the brake or the brake disc and/or a pressure within the brake can be used for this purpose.

If the remaining service life determined by the first machine learning system (60) reaches or falls below a predefined remaining service life, the control system (40) can control an actuator (10) of the motor vehicle (100) accordingly by means of the control signal (A) in order to reduce a range of functions of the actuator (10). It is in particular conceivable that the actuator (10) is a drive of the motor vehicle (100) and the control signal (A) controls the drive such that a maximum speed of the motor vehicle (100) is reduced.

The control signal (A) can alternatively or additionally be used to control the display unit (10a). For example, the display unit (10a) can show the remaining service life determined by the first machine learning system (60) on a display. The display unit (10a) can alternatively or additionally be controlled with the control signal (A) such that it outputs an optical or acoustic warning signal if it is determined that the determined remaining service life has reached or has fallen below the predefined remaining service life. This can also be accomplished by means of a haptic warning signal, for example via a vibration of a steering wheel of the motor vehicle (100).

The motor vehicle (100) can alternatively also be an electric motor vehicle or a hybrid motor vehicle with an electric motor and the first machine learning system (60) can be configured to determine a remaining service life of a battery of the motor vehicle (100). For this purpose, the input signals (x) of the first machine learning system can preferably be determined based on sensor signals (S) from one or more sensors (30) which are configured to determine a temperature of the battery and/or a voltage of the battery and/or an ambient temperature of the battery. If the remaining service life determined by the first machine learning system (60) reaches or falls below a predefined remaining service life, an electric drive (10) of the motor vehicle (100) can, for example, be controlled such that an acceleration of the drive and/or the vehicle is reduced.

The at least partially autonomous robot can alternatively also be another mobile robot (not shown). The mobile robot can also be an at least partially autonomous lawnmower or an at least partially autonomous cleaning robot, for example.

FIG. 4 shows an embodiment example in which the control system (40) is used to control a manufacturing machine (11) of a manufacturing system (200) by controlling an actuator (10) which controls said manufacturing machine (11). The manufacturing machine (11) can in particular be configured to process a workpiece (12a, 12b), in particular a blank. The manufacturing machine (11) can be a machine for punching, sawing, drilling, etching, welding, soldering, cutting and/or equipping the workpiece (12a, 12b), for example. It is also conceivable that the manufacturing machine (11) is configured to grip the workpiece (12a, 12b) by means of a gripper.

To process the workpiece (12a, 12b), the manufacturing machine (11) can in particular comprise a movable arm, by means of which the workpiece (12a, 12b) is processed. The arm can in particular be moved by the actuator (10). The actuator (10) can in particular be a drive, for example via a hydraulic drive or an electric drive. In the embodiment example, the drive can be considered a component of the manufacturing machine (11), in which case the drive can be subject to a wear process. The sensor (30) is configured to be able to determine an operating state of the drive, in particular a current consumption and/or a torque and/or a pressure and/or a force.

The sensor signal (S) characterizing the operating state is then sent to the control system (40) to determine a remaining service life of the component.

The determined remaining service life can then be shown on a display included in the display device (10a). Alternatively, it is also conceivable that a minimum expected remaining service life, an average expected remaining service life and a maximum expected remaining service life is determined by the control system (40), wherein the three expected remaining service lives are shown on the display.

Alternatively or additionally, the range of functions of the drive can be reduced if the determined remaining service life reaches or falls below a predefined remaining service life. For example, it is possible that a maximum acceleration of the drive or a maximum torque of the drive is reduced.

Alternatively or additionally, it is also possible that, when the predefined remaining service life is reached or fallen short of, an inspection of the manufacturing machine (11) is automatically requested or the actuator (10) is automatically replaced with a new actuator (10).

In alternative embodiment examples, the manufacturing machine (11) comprises at least one fluid-carrying line (not shown), which can be understood as a component of the manufacturing machine (11), wherein the at least one fluid-carrying line is subject to a wear process, in particular due to the flow of fluid though the line. At least one sensor (30) of the manufacturing machine (11) is configured to determine an operating state of the at least one fluid-carrying line, in particular a pressure inside the at least one fluid-carrying line and/or a quantity of fluid which flows through the fluid-carrying line in a predefined period of time and/or a temperature of the fluid-carrying line and/or a temperature of the manufacturing machine (11), and transmit it as a sensor signal (S) to the control system (40). The control system (40) is configured to determine a remaining service life of the at least one fluid-carrying line and to control a pump (10) that pumps a fluid through the at least one fluid-carrying line.

If the remaining service life determined by the control system (40) reaches or falls below a predefined remaining service life, the range of functions of the pump (10) can be reduced. In particular a maximum pumping quantity of the pump (10) can be reduced, or the pump (10) can be taken out of service. As in the previous embodiment examples, it is also possible here for at least one remaining service life determined by the control system (40) to be shown on the display (10a).

FIG. 5 shows an embodiment example in which the control system (40) is used to control a household appliance (300). The household appliance (300) comprises fluid-carrying lines, in particular water-carrying lines, which can be understood as components of the household appliance (300). The household appliance (300) can in particular be a dishwasher or a washing machine. The at least one sensor (30) and the control system (40) operate in an analogous manner.

The household appliance (300) comprises at least one sensor (30) that determines an operating state, a pressure within at least one component and/or a quantity of fluid that flows through the component in a predefined period of time and/or a temperature of the component and/or a temperature of the household appliance (300).

At least one sensor (30) of the household appliance (300) is configured to determine an operating state of the at least one fluid-carrying line, in particular a pressure inside the at least one fluid-carrying line and/or a quantity of fluid which flows through the fluid-carrying line in a predefined period of time and/or a temperature of the fluid-carrying line and/or a temperature of the household appliance (300), and transmit it as a sensor signal (S) to the control system (40). The control system (40) is configured to determine a remaining service life of the at least one fluid-carrying line and to control a pump (10) that pumps a fluid through the at least one fluid-carrying line.

If the remaining service life determined by the control system (40) reaches or falls below a predefined remaining service life, the range of functions of the pump (10) can be reduced. In particular a maximum pumping quantity of the pump (10) can be reduced, or the pump (10) can be taken out of service. As in the previous embodiment examples, it is also possible here for at least one remaining service life determined by the control system (40) to be shown on the display (10a) of the household appliance (300).

FIG. 6 shows an embodiment example of a training system (140) for training the first machine learning system (60) of the control system (40) by means of a training data set (T). The training data set (T) comprises a plurality of input signals (xᵢ) that can be used to train the classifier (60). The input signals (xᵢ) respectively characterize measurements of at least one sensor of a technical system. The input signals are furthermore assigned remaining service lives.

For training, a training data unit (150) accesses a computer-implemented database (St₂), wherein the database (St₂) provides the training data set (T). The training data unit (150) preferably randomly determines at least one input signal (xᵢ) from the training data set (T) and transmits the input signal (xᵢ) to the first machine learning system (60). The first machine learning system (60) determines a third representation on the basis of the input signal (xᵢ) and by means of the encoder (61). The third representation is fed to a decoder of the first machine learning system (60) which is configured to determine a reconstruction (\hat{x}ᵢ) of the input signal (xᵢ) on the basis of the third representation, wherein the reconstruction (\hat{x}ᵢ) has the same dimensionality as the input signal (xᵢ). If the encoder (61) is the encoder of an autoencoder, the decoder is the corresponding decoder of the autoencoder. If the encoder (61) is the encoder of a variational autoencoder, the decoder is the corresponding decoder of the variational autoencoder. If the encoder (61) is the forward pass of a normalizing flow, the decoder is the backward pass of the normalizing flow.

The input signal (xᵢ) and the reconstruction (\hat{x}ᵢ) are transmitted to a change unit (180).

New parameters (Φ′) for the machine learning system (60), in particular for the encoder (61), are then determined by the change unit (180) on the basis of the input signal (xᵢ) and the reconstruction (\hat{x}ᵢ). For this purpose, the change unit (180) compares the input signal (xᵢ) with the reconstruction (\hat{x}ᵢ) by means of a loss function. The loss function determines a first loss value that characterizes how far the reconstruction (\hat{x}ᵢ) deviates from the input signal (xᵢ). In the embodiment example, a negative log-likehood function is selected as the loss function. In alternative embodiment examples, other loss functions are conceivable as well, for example a Euclidean loss function.

The change unit (180) determines the new parameters (Φ′) on the basis of the first loss value. In the embodiment example, this is accomplished by means of a gradient descent method, preferably by means of stochastic gradient descent or Adam or AdamW.

The determined new parameters (Φ′) are stored in a model parameter memory (St₁). The determined new parameters (Φ′) are preferably provided as parameters (Φ′) to the classifier (60).

In further preferred embodiment examples, the described training is iteratively repeated for a predefined number of iteration steps or iteratively repeated until the first loss value falls below a predefined threshold value. Alternatively or additionally, it is also conceivable that the training is ended when an average first loss value with respect to a test or validation data set falls below a predefined threshold value. In at least one of the iterations, the new parameters (Φ′) determined in a previous iteration are used as parameters (Φ) of the classifier (60).

After training, the encoder (61) determines the respective representations for at least one subset of input signals (xᵢ) of the training data set (T) and provides the determined representations as second representations to the first machine learning system (60). Corresponding remaining service lives are assigned to the second representations based on the remaining service lives of the second representations.

The training system (140) can furthermore comprise at least one processor (145) and at least one machine-readable storage medium (146), which includes instructions that, when executed by the processor (145), prompt the training system (140) to carry out a training method according to any one of the aspects of the invention.

The term “computer” includes any device for processing predeterminable calculation rules. These calculation rules can be available in the form of software, in the form of hardware or also in a mixed form of software and hardware.

A plurality can be generally be understood as being indexed, i.e., each element of the plurality is allocated a unique index, preferably by allocating consecutive whole numbers to the elements included in the plurality. If a plurality comprises N elements, wherein N is the number of elements in the plurality, the elements are preferably allocated whole numbers from 1 to N.

1. A computer-implemented method for determining a remaining service life of at least one component of a technical system, comprising:
determining a first input signal by way of at least one sensor, wherein the first input signal characterizes an operating state of at least the component of the technical system;
determining a first representation of the first input signal by way of an encoder of a first machine learning system; and
determining the remaining service life on the basis of the first representation and on the basis of a provided plurality of second representations, wherein the plurality of second representations is determined on the basis of a plurality of second input signals by way of the encoder and a corresponding remaining service life is assigned to each second representation.

2. The method according to claim 1, wherein:
in the step of determining the remaining service life, the remaining service life is determined depending on at least one similarity of one of the second representations to the first representation.

3. The method according to claim 2, wherein:
in the step of determining the remaining service life, the remaining service life is determined depending on the remaining service life of the one of the second representations.

4. The method according to claim 3, wherein:
in the step of determining the remaining service life, the remaining service life assigned to a second representation is provided as the determined remaining service life, and wherein
the second representation is the one of the plurality of second representations that is most similar to the first representation.

5. The method according to claim 3, wherein:
in the step of determining the remaining service life, an average or a median or a minimum or a maximum of remaining service lives corresponding to a subset of the plurality of second representations is provided as the determined remaining service life, and wherein
the subset includes a predefined number of second representations most similar to the first representation.

6. The method according to claim 1, wherein:
the remaining service life is determined by way of a second machine learning system, and wherein
the second machine learning system is initially trained by way of the plurality of second representations and the remaining service lives respectively assigned to the second representations such that it can determine a remaining service life for the first representations.

7. The method according to claim 1, wherein the encoder of the first machine learning system is trained by way of the plurality of second input signals.

8. The method according to claim 1, wherein:
the first representation is transmitted to a second device by way of a network connection of the technical system, and
the step of determining the remaining service life is carried out by the second device.

9. The method according to claim 1, wherein the first representation is held available by the technical system and/or the second device together with a measurement time for the input signal and, at an end of life of at least the component of the technical system, the first representation is included as a second representation in the plurality of the second representations, and wherein the remaining service life corresponding to the first representation is determined by a difference of a time of the end of life and the measurement time.

10. The method according to claim 1, wherein the determined remaining service life is communicated to an operator and/or a user of the technical system by way of a display device.

11. The method according to claim 1, wherein at least the component of the technical system is replaced if the determined remaining service life reaches or falls below a predefined minimum remaining service life.

12. System A system for data processing, comprising means for carrying out the method according to claim 1.

13. System A system for data processing, comprising means for training the machine learning system according to claim 7.

14. Computer A computer program configured to carry out the method according to claim 1 when executed by a processor.

15. Machine readable A machine-readable storage medium on which the computer program according to claim 14 is stored.
